(19) United States
(12) Patent Application Publication
(10) Pub. No.: US 2010/0119708 A1
(43) Pub. Date: May 13, 2010

(54) Filling structures of high aspect ratio elements for growth amplification and device fabrication

(75) Inventors: Lawrence J. Overzet, Richardson, TX (US); Gil S. Lee, Plano, TX (US); Anand Chandrashekar, Richardson, TX (US); Seetharaman Ramachandran, Plano, TX (US); Jeong-Soo Lee, Yongin-City (KR); Slade H. Gardner, Fort Worth, TX (US)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignees: BOARD OF REGENTS THE UNIVERSITY OF TEXAS SYSTEM, AUSTIN, TX (US); LOCKHEED MARTIN CORPORATION

(21) Appl. No.: 11/391,016

(22) Filed: Mar. 28, 2006

(51) Int. Cl. C23C 16/00; B32B 5/02

(52) U.S. Cl. 427/212; 428/315.7; 977/742

(57) ABSTRACT

The present invention includes compositions, devices and methods for filling structures of high aspect ratio elements for growth amplification and device fabrication. A method includes a method of filling a structure comprising the steps of providing one or more structures, each structure having a plurality of high aspect ratio elements, wherein the aspect ratio is at least 5; and coating the plurality of high aspect ratio elements with at least one solidifying material produced by a form of chemical vapor deposition thereby forming a structured-film. Compositions of the present invention are solid formed structures that are less fragile, do not require such delicate handling to avoid serious degradation, are more stable, last longer, do not deform, and exhibit little stress as well as improved properties that include mechanical, chemical, electrical, biologic, and optical.

### CROSS-REFERENCE TO RELATED APPLICATION

Not applicable.

### STATEMENT REGARDING FEDERALLY SPONSORED APPLICATIONS

Not applicable.

### BACKGROUND OF THE INVENTION

The present invention relates to compositions, devices and methods of filling structures, particularly structures comprising a plurality of high aspect ratio elements.

Deposition of one or more materials on a structure to form a composition or device with high electrical conductivity, thermal conductivity and mechanical strength have met with some success, but also have many limitations. Such structures, particularly those having a plurality of high aspect ratio elements can be very fragile. An example of such high aspect ratio elements are carbon nanotubes (CNTs). CNTs are often grown as a forest on a substrate using a variety of processes, and while individual CNTs have great strength, forests are found generally to be very fragile because individual CNTs exhibit very weak connections to one another and to the substrate. This can necessitate delicate handling to avoid serious degradation and deformation to the CNT forest. The fragility has prevented the widespread application of CNTs and CNT forests. As such, there remains a need to improve the stability of structures comprising a plurality of high aspect ratio elements, such as CNTs.

Structures having a plurality of high aspect ratio elements, such as CNTs, exhibit many exciting properties, such as high electrical conductivity, high thermal conductivity, and high mechanical strength. Accordingly, composite structures have been developed in which dispersed high aspect ratio elements, such as CNTs, contribute their beneficial properties (e.g., high electrical conductivity, high thermal conductivity, and high mechanical strength) to the composite structure. For example, incorporating CNTs into a brittle and electrically insulating ceramic matrix helps increase fracture toughness and electrical conductivity of the matrix. Unfortunately, incorporation requires uniform dispersion of CNTs in the matrix which, in turn, is possible only by elaborate post-processing. Therefore, there remains a need to prepare and provide a more uniform dispersion of high aspect ratio elements, particularly in a manner that does not deform the original structure.

It is also difficult to deposit typical materials for electronics and micro-electro-mechanical systems (MEMS), such as polysilicon, silicon nitride, metals and polymers, to thicknesses of several tens of micrometers. While many techniques are too slow; others produce films that are too thick. For example: low pressure chemical vapor deposition technologies tend to be slow (typically around 1 μm per hour). Thus, depositing materials as films that are tens of micrometers thick requires tens of hours and quickly becomes infeasible. In addition, the internal stress in such films can become high; leading to a variety of film degradation effects. Therefore, there remains a need to deposit electronic and MEMS materials as films in a manner that is more cost-effective and saving time, reduce internal stress to the film and prevent film degradation.

### SUMMARY OF THE INVENTION

The present invention solves problems indicated above, including forming stable structures comprising a plurality of high aspect ratio elements and providing high aspect ratio structures that are more uniformly dispersed. In addition, the present invention provides improvements over the current and slow deposition rate of films and alleviates internal stress to the film and film degradation effects.

The present invention overcomes current issues associated with the fragile and delicate nature of high aspect ratio elements synthesized in forests, yarns, strings, fibers, paper, glancing angle deposits and the like. In one form, the present invention provides for mechanically stronger interconnections between a substrate surface and a high aspect ratio element and between high aspect ratio elements. In another form, the present invention provides for mechanically stronger composite structures comprised of high aspect ratio elements. The mechanically stronger composite structures are prepared in accordance with one or more select and defined properties (e.g., more electrically conductive, more electrically insulating, more thermally conductive, chemically functionalized). Accordingly, composite structures of the present invention are prepared as desired and convey such properties to the devices created therefrom.

Compositions of the present invention are prepared by filling one or more structures having a plurality of high aspect ratio elements. Filling includes coating the plurality of high aspect ratio elements with a solidifying material. The solidifying material is provided typically by chemical vapor deposition. The solidifying material may include polysilicon or silicon nitride, as examples. The method fills spaces between high aspect ratio elements to a desired degree thereby providing a composite structure also referred to herein as structured film. The coating process is typically continued in order to coat an exposed surface of individual high aspect ratio elements. The solidifying materials do not deform the original structure. Each structure may include a plurality of high aspect ratio elements provided as a forest, yarn, fiber, paper, strings, or the like. The plurality of high aspect ratio elements may also be arranged as a filter, membrane or as high aspect ratio trenches. High aspect ratio elements may be as long as or longer than 50 μm.

As provided herein, the method of filling one or more structures may occur to any desired endpoint to create a conductive composite structure, insulating composite structure, membranous composite structure or the like having a desired sheet resistance, hardness, mechanical strength and/or density as needed.

In another form, a method of the present invention provides for preparing select and defined compositions. The method includes growing one or more structures having a plurality of high aspect ratio elements on a substrate and coating the plurality of high aspect ratio elements with a solidifying material. The solidifying material may be grown to any desired endpoint to provide a defined thickness of solidifying material around each high aspect ratio element. Coating may be repeated one or more times to prepare a layered composite structure, wherein the solidifying material in each step is the same or different. When desired, electrical connections may be included in order for such compositions to behave like an electrical device. The solidifying material and/or its thickness promotes the formation of a composite structure having any desired sheet resistance, hardness, and/or density as needed. When desired, the step(s) of coating may be followed by a removal of the one or more structures and/or substrate using processes known to one of ordinary skill in the art, such as etching. Similarly, when desired, the composite structure may be further processed by post-processing techniques known to one of ordinary skill in the art, such as polishing, annealing, etching, as examples.

Advantages of the present invention are many, including providing truly stable and long-lasting solid structures having a plurality of high aspect ratio elements and providing a method for depositing typical electronic and MEMS materials to thicknesses greater than a few micrometers. Devices prepared by compositions of the present invention are not limited to the field of electronics but can be applied for use in chemical, optical, biologic and mechanical technologies as well.

Those skilled in the art will further appreciate the above-noted features and advantages of the invention together with other important aspects thereof upon reading the detailed description that follows in conjunction with the drawings.

### BRIEF DESCRIPTION OF SEVERAL VIEWS OF THE DRAWINGS

For more complete understanding of the features and advantages of the present invention, reference is now made to the detailed description of the invention along with the accompanying figures, wherein:

FIG. 1A and FIG. 1B depict schematics of representative structures of the present invention, each structure comprising a plurality of high aspect ratio elements;

FIG. 2 depicts a schematic of yet another representative structure of the present invention;

FIG. 3 depicts a schematic of additional representative structures of the present invention, each structure residing on a substrate;

FIG. 4 depicts a schematic of still additional representative structures of the present invention, each structure residing on a substrate;

FIG. 5 depicts a micrograph obtained by scanning electron microscopy (SEM) of still another representative structure comprising high aspect ratio elements residing on a substrate;

FIG. 6 depicts a micrograph obtained by SEM of still another representative structure comprising high aspect ratio elements residing on a defined portion of a substrate;

FIG. 7 depicts in cross section a micrograph obtained by SEM of a structure comprising a plurality of high aspect ratio elements, wherein each element is vertically defined on a substrate;

FIG. 8A depicts a schematic of a representative structure filled in accordance with one aspect of the present invention;

FIG. 8A depicts a schematic of additional representative structures filled in accordance with another aspect of the present invention, wherein representative structures reside on a defined portion of a substrate;

FIG. 9 depicts in cross section a micrograph obtained by SEM of a structure residing on a substrate and comprising 5 μm tall CNTs after coating with a solidifying material in accordance with one aspect of the present invention;

FIG. 10A depicts in cross section a micrograph obtained by SEM of a structure residing on a substrate and comprising 50 μm tall CNTs after coating with a solidifying material in accordance with another aspect of the present invention;

FIG. 10B depicts in cross section a micrograph obtained by SEM of a structure residing on a substrate and comprising 74 μm tall CNTs after coating with a solidifying material in accordance with another aspect of the present invention;

FIG. 11 depicts in cross section a micrograph obtained by SEM of a structure residing on a substrate and comprising 50 μm tall CNTs after coating with a solidifying material in accordance with still another aspect of the present invention;

FIG. 12 depicts in cross section a micrograph obtained by SEM of a structure as depicted in FIG. 7 after coating with a solidifying material in accordance with still another aspect of the present invention;

FIG. 13A depicts in cross section a micrograph obtained by SEM of more than one structure of the present invention;

FIG. 13B depicts in cross section a micrograph obtained by SEM of the structures depicted in FIG. 13A after coating with a solidifying material in accordance with yet another aspect of the present invention;

FIG. 14 depicts a micrograph obtained by SEM of an individual high aspect ratio elements in cross section after coating with a solidifying material in accordance with still another aspect of the present invention; and

FIG. 15 depicts in cross section a micrograph obtained by SEM of structure residing on a substrate and comprising 50 μm tall CNTs after coating with a solidifying material to a desired thickness in accordance with still another aspect of the present invention.

### DETAILED DESCRIPTION

Although making and using various embodiments of the present invention are discussed in detail below, it should be appreciated that the present invention provides many inventive concepts that may be embodied in a wide variety of contexts. The specific aspects and embodiments discussed herein are merely illustrative of ways to make and use the invention, and do not limit the scope of the invention.

In the description that follows like parts are marked throughout the specification and drawing with the same reference numerals, respectively. The drawing figures are not necessarily to scale and certain features may be shown exaggerated in scale or in a somewhat generalized or schematic form in the interest of clarity and conciseness.

In general, the present invention provides compositions comprising one or more structures having a plurality of high aspect ratio elements and filling such structures thereby preparing composite structures (structured films). The structured films are of any desired thickness with properties that can be controlled, in part, by filling. Such properties include electrical, thermal, chemical, biologic, optical and mechanical properties that are initially dictated by the structure and the plurality of high aspect ratio elements. Filling includes coating the plurality of high aspect ratio elements using a form of chemical vapor deposition. Coating occurs as gas phase molecules dissociate and stick to exposed surfaces of the structure. Accordingly, coating occurs wherever there is a surface that gas phase molecules can stick to, react and form a solid. Such surfaces may include not only exposed surfaces of the high aspect ratio elements as well as any support or substrate on which the structure resides on or is in contact with. A material used for coating is referred to herein as solidifying material.

One feature of the present invention is that each structure of the present invention has a plurality of high aspect ratio elements. High aspect ratio elements are defined as elements with a length-to-width ratio, a height to width ratio, a height-to-diameter ratio or a length-to-diameter ratio that is high aspect; the ratio typically greater than 5. The plurality of high aspect ratio elements may be organized into quasi 1-dimesional (linear), quasi 2-dimensional (areal) or 3-dimensional (volumetric) spaces to form the structure. Examples include: (quasi 1-dimensional) filaments, fibers, strings, yarns; (quasi 2-dimensional) papers, membranes, cylinders, spheres; (3-dimensional) forests, filters, balls, and the like. Structures have an overall dimension (e.g., length, width, height) that is larger than the typical spacing (e.g., distance) between high aspect ratio elements. The ratio for the overall dimension of the structure to the spacing between adjacent elements is typically 5 or greater.

One or more elements of the same or differing material may be combined to form a structure and one or more structures may be combined, as long as each structure comprises a plurality of high aspect ratio elements.

One feature of a structure of the present invention is that it is constructed from a material able to withstand elevated temperatures as further described herein for providing compositions and devices of the present invention.

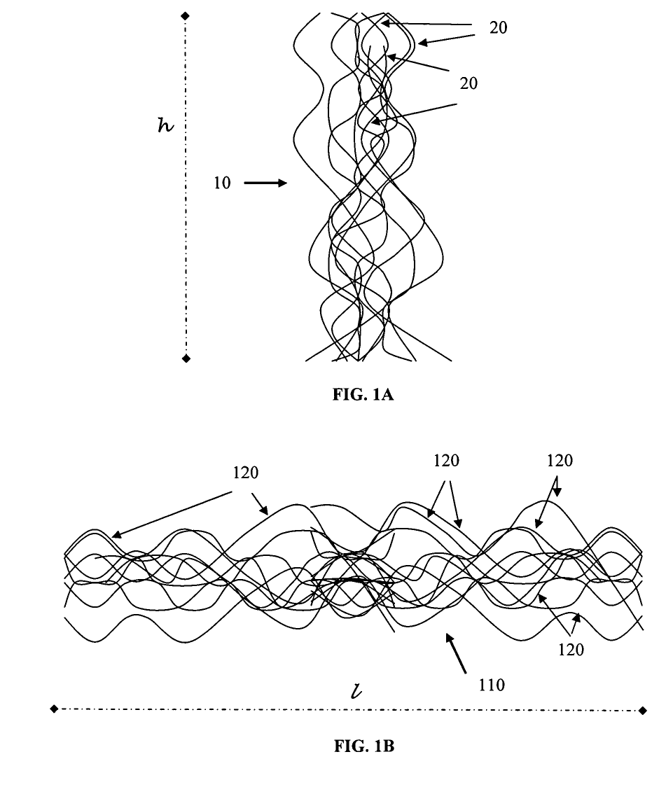

Referring now to FIGS. 1A and 1B, representative structures of the present invention are depicted schematically as structures 10 and 110, respectively. Structure 10 comprises a plurality of high aspect ratio elements 20. Elements 20 are not necessarily identical nor do they always have the same dimensions, shapes or properties. Structure 10 has an overall height, h; however individual elements 20 may have a different height that is not necessarily identical to h. Elements 20 are also spaced closer than the overall dimension (h) of structure 10. Likewise, structure 110 in FIG. 1B comprises a plurality of high aspect ratio elements 120 with has an overall length, l. Individual elements 120 may have lengths that are similar to or are different from l. In addition, elements 120 are spaced closer than the overall dimension (l) of structure 110.

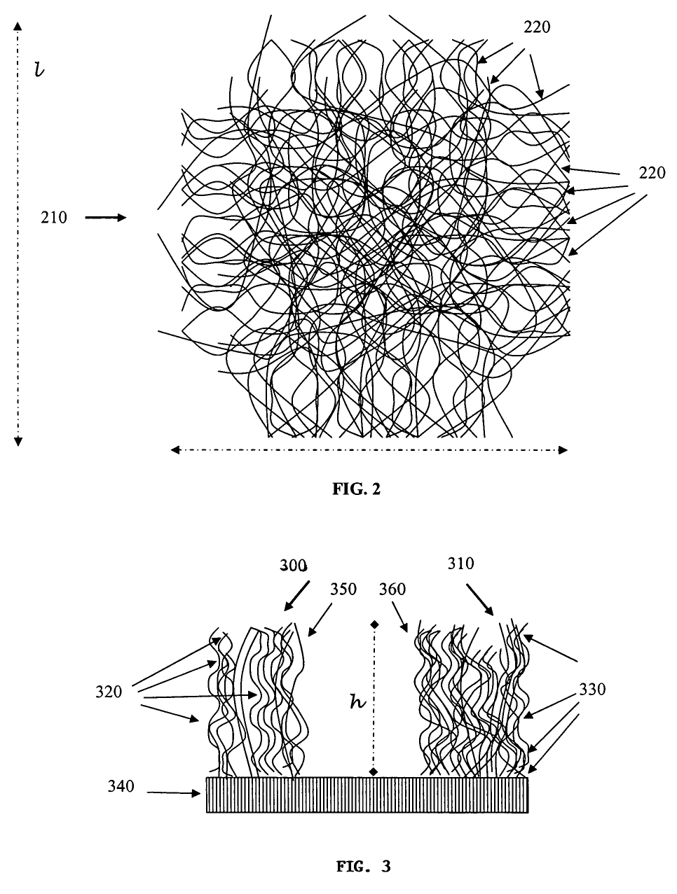

A schematic of a quasi 2-dimensional structure is shown in FIG. 2 which includes structure 210 comprising a plurality of high aspect ratio elements 220. Elements 220 are not necessarily identical nor do they always have the same shape, dimension(s) or properties. Elements 220 are also not necessarily identical in dimension, shape or property as structure 210. However, elements 220 are spaced typically closer than the overall dimension (l , w) of structure 210. Typically, spacing (e.g., distance) between adjacent high aspect ratio elements 220 is at least a factor of 5 or less than the overall dimension of structure 210.

With the present invention, the one or more structures of the present invention may reside on or be in contact with a support or substrate, the support or substrate being any desired shape or in any desired location with reference to the structure(s). A representative example of one or more structures residing on a substrate is shown in FIG. 3. Here, two structures 300 and 310 each comprise a plurality of high aspect ratio elements, namely elements 320 and 330, respectively. High aspect ratio elements 320 and 330 have uppermost portions 350 and 360, respectively, when residing on a platform or structure. As an alternative, or in addition, high aspect ratio elements may have end portions at the outermost ends of a structure. Structures 300 and 310 have an overall height, h, and reside on substrate 340, which may or may not have additional patterning.

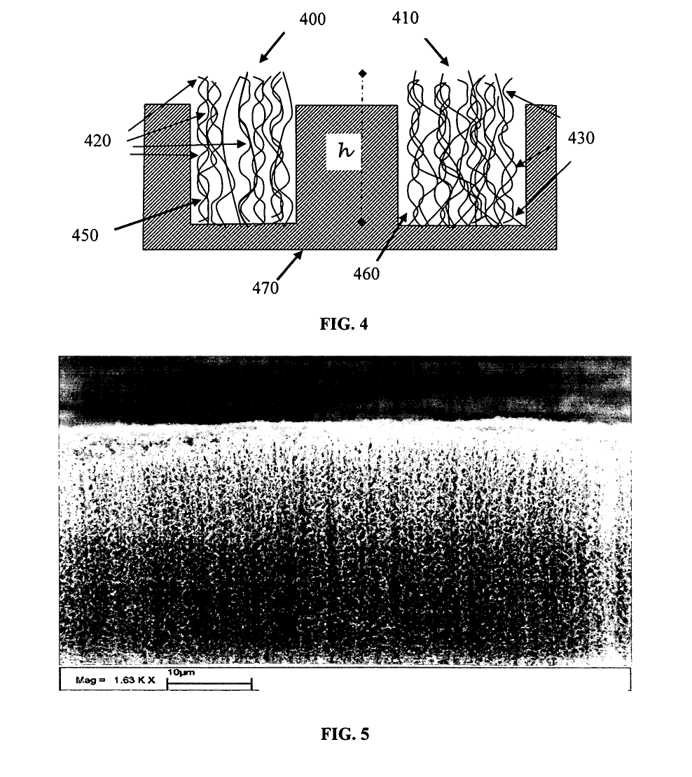

A representative example of a patterned substrate is shown schematically in FIG. 4 in which two regions 450 and 460 are patterned (e.g., etched) into substrate 470. In region 450 is structure 400 and in region 460 is structure 410. Each structure, 400 and 410, comprise a plurality of high aspect ratio elements, namely elements 420 and 430, respectively. Unlike that which is depicted in FIG. 4, the dimensions of each structure of the present invention are not necessarily limited by the dimensions of a support or substrate it resides on or the patterns provided in the support substrate. For example, referring back to FIG. 4, the lateral extent (width) of either structure 400 or 410 need not be limited by the cross-sectional diameter of region 450 or 460, respectively. In addition, height, h, of each structure is not limited by the depth of region 450 or 460. Moreover, each structure on a substrate need not be identical or of an identical height.

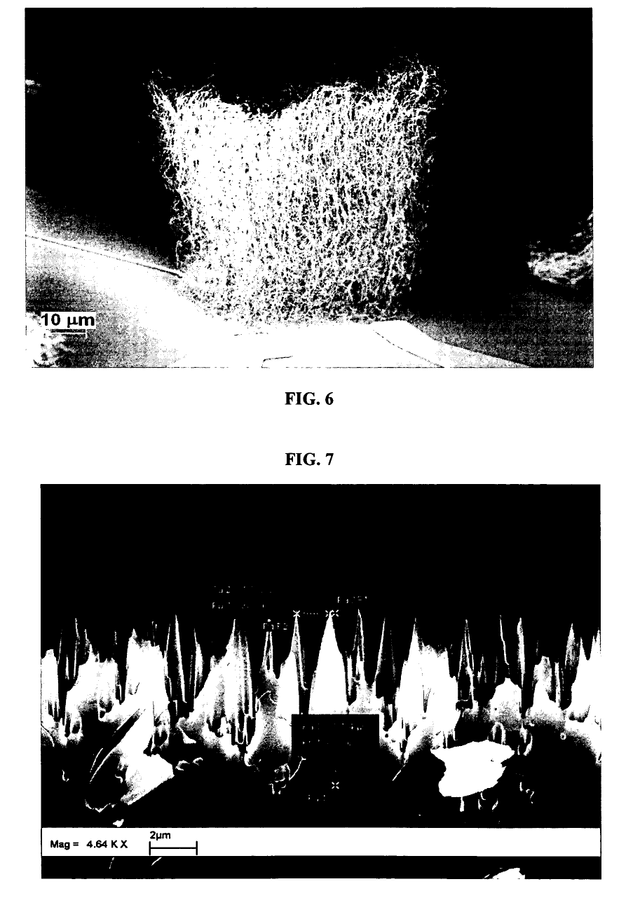

In one form, an example of a high aspect ratio element is a CNT, a plurality of which may comprise a forest, as depicted in FIGS. 5 and 6. Additional examples are filamentous materials such as nanotubes, nanofilaments, rods, wires, cones and pillars because they have a high aspect ratio. Further examples include trenches, vias, holes and other high aspect ratio shapes typically prepared by etching techniques known to one of ordinary skill in the art, an example of which is depicted in FIG. 7. High aspect ratio elements may be made of carbon or any other materials, such as silicon and boron nitride, capable of forming an element having a high aspect ratio. The material of the high aspect ratio elements and the form of the structure impart the properties to the structure. Accordingly, each structure, as provided herein, may have any manner of property, examples of which include electrically insulating, conducting or semi-conducting, membranous or filtering, optically transmissive, reflective or polarizing, mechanically strong, stressed, or ductile, biologically sensitive or non-fouling, chemically active or catalyzing, magnetic, diamagnetic or paramagnetic, thermally insulating or conducting and combinations thereof. One or more structures may be further arranged, patterned or connected to a circuit. In addition, a structure and/or its related elements may be electrically connected to external circuitry to provide a desired device. An example of such a device is a capacitor or a transistor. In the case of a capacitor, the large surface area provided by the high aspect ratio elements is valuable in manufacturing capacitors of large charge storage capacity.

Referring now to FIG. 5, the figure depicts a plurality of CNTs grown as a forest on a substrate. The overall height of the forest is greater than the typical distance between adjacent CNTs. The forest or structure is continuous on the substrate. This is unlike a structure as depicted in FIG. 6, in which a discrete and defined forest is depicted on a substrate. In FIG. 6, the structure is further connected to electrodes of a testing circuit.

A support or substrate as provided herein may be any suitable material that is compatible with structures of the present invention, including their growth or placement, and are able to withstand elevated temperatures as described herein for providing compositions and devices of the present invention. Examples of a support or substrate include a wafer, circuit, filter, membrane, cylinder, sphere, block or template. Suitable support or substrate materials are those that are compatible with the growth or placement of the aforesaid structures, including semiconductor materials (e.g., gallium-arsenide, silicon or other substrates that may be used in integrated circuit fabrication), insulating materials (e.g., quartz slides), single metals (e.g., copper, titanium sheets etc.), metal alloys (e.g., stainless steel, nickel-chromium, titanium-aluminum-vanadium parts), and organic materials (e.g., polymers, diamond, graphite). The materials may further enhance, promote, counteract or provide sense properties to structures of the present invention.

A support or substrate as provided herein may also include surface modifications, such as oxidations, etchings, thin or thick film depositions or patterning. Moreover, a support or substrate may have its own properties, for example electrical, mechanical, optical, biologic or chemical properties. In combination, a structure plus a support or substrate may provide useful properties such as high electrical conductivity, insulation, sensing capabilities, signal processing, filtering functions (e.g., electronic, chemical, optical filtering), and signal integration functions.

As described further, a method of the present invention includes filling one or more structures which includes coating the plurality of high aspect ratio elements of the one or more structures with a solidifying material to form stable, stronger, or thicker structures (typically composite structures) having desirable properties using a form of chemical vapor deposition (CVD). When filled completely, structures of the present invention are solid and absent or nearly free of voids or spaces. Incomplete filling, for example when coating with a thin layer of solidifying material, may promote more voids or spaces. Filled structures (typically composite structures) provide valuable properties to such structures that will be appreciated to those of ordinary skill in the art.

Another feature of the present invention includes providing coating conditions wherein (precursor) molecules of the solidifying material have either a small surface sticking coefficient or a limited surface reaction capability. CVD (e.g., low pressure chemical vapor deposition [LPCVD], plasma enhanced chemical vapor deposition [PECVD], atmospheric pressure CVD, metal organic CVD) and atomic layer deposition (ALD) fit such conditions by providing a substantially uniform thickness of solidifying material to coat individual high aspect ratio elements and preventing or reducing capping or matting down of the structure.

Using LPCVD as an example; thermal energy is used to decompose precursor molecules of the solidifying material, the energy for decomposition being provided through collisions of the precursor molecules with exposed surfaces of the structures that also allow growth of the solidifying material as a film. As is obvious to one of ordinary skill in the art, thermal energy may be provided by a furnace-type apparatus or a planar apparatus, such as a hot plate, heater block, heating pad etc.

With the present invention, coating is either extended in time or repeated to obtain a filled structure, referred to herein as structured film. Suitable solidifying materials of the present invention are solids that are capable of being coated onto and solidifying around a plurality of high aspect ratio elements with substantial uniformity. Examples of solidifying materials include semiconductor materials, insulating materials, metals, polymers and combinations thereof. Semiconductor materials may include polysilicon (doped or undoped), amorphous silicon, gallium arsenide, and germanium, as examples. Insulating materials may include silicon nitride (Si₃N₄), silicon dioxide, alumina and ceramics, as examples. Metals may include tungsten, aluminum, vanadium, nickel and copper, as examples. Polymers may include fluoropolymers in addition to other forms of carbon such as amorphous carbon, diamond or diamond-like carbon.

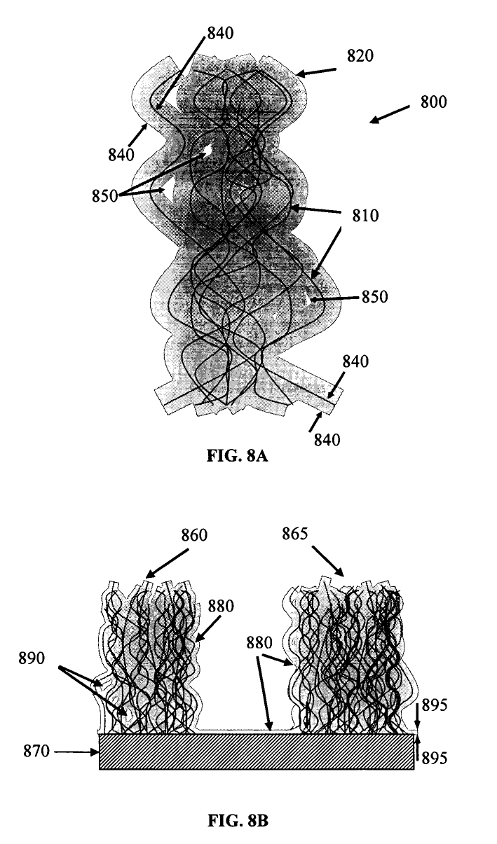

With the present invention, the one or more structures are filled by coating individual high aspect ratio elements with at least one solidifying material thereby forming a structured film. Representative schematics of structures having a plurality of high aspect ratio elements, wherein the plurality of high aspect ratio elements are coated by a solidifying material in accordance with various aspects of the present invention are shown in FIGS. 8A and 8B. In FIG. 8A, a structure comprising a plurality of high aspect ratio elements 810 is filled by coating the plurality of high aspect ratio elements 810 with a solidifying material 820, thereby forming a structured film 800. Filling may leave voids 850, typically due to irregularities in the structure and/or duration of filling.

FIG. 8B depicts two structures residing on substrate 870. Both structures comprise a plurality of high aspect ratio elements and are filled by coating with a solidifying material 880, thereby forming structured films 860 and 865. As is known to one of ordinary skill in the art, forming of structured films 860 and 865, both residing on substrate 870, will also provide solidifying material 880 on the exposed surface of substrate 870. Filling may also leave voids as depicted by 890. As shown in FIGS. 8A and 8b, the thickness of solidifying material 820 and 880 (also referred to herein as coating thickness) is shown to lie between arrows 840 in FIG. 8A and arrows 895 in FIG. 8B, which is typically near or about half the diameter (in cross section) of the solidifying material 820 and 880, respectively, on an individual high aspect ratio element.

Additional examples of filling structures by coating with one or more solidifying materials are presented herein in which polysilicon and silicon nitride (Si₃N₄) are representative solidifying materials. In the examples, polysilicon and Si₃N₄ were deposited via LPCVD using a standard LPCVD furnace (as used in the semiconductor manufacturing industry). Polysilicon was coated using a feed gas of 75 standard cubic centimeters per minute (sccm) of silane at a furnace temperature of about 630 degrees Centigrade. Si₃N₄ was coated by flowing 75 sccm of ammonia and 25 sccm of dichlorosilane at a temperature of about 730 degrees Centigrade. Both filling methods were performed at a pressure of about 250 mTorr and for a time period commensurate with a desired final coating thickness (typically less than 1 hour). One of ordinary skill in the art will appreciate that the duration of coating, the furnace temperature, the gases introduced, and the flow rates of those gases factor in to provide the final coating thickness as well as the uniformity of coating thickness on a high aspect ratio element.

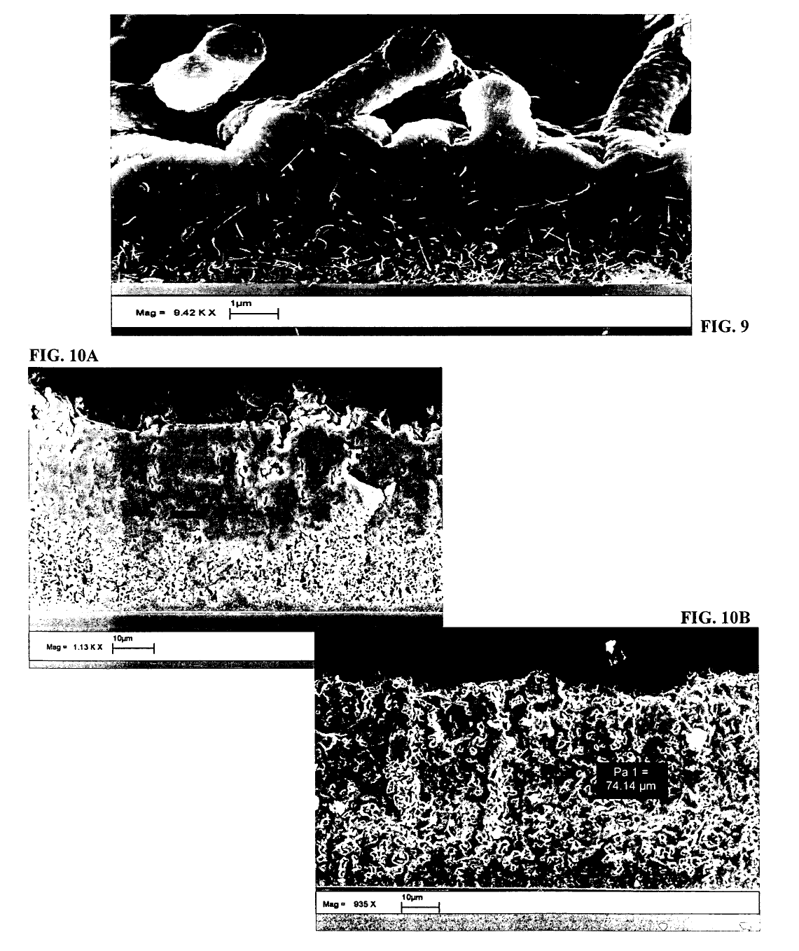

Referring now to FIG. 9, multi-walled CNTs as high aspect ratio elements were grown in a short 5.0 μm forest (structure) on a silicon substrate. The structure was subsequently filled to provide a coating thickness of approximately 0.6 μm of polysilicon in about 40 minutes to provide a structured film that was approximately 4.5 μm thick. The diameter of coated polysilicon around each CNT was approximately 1.2 μm. It is noted that the cracking process used to expose the structure for SEM left some CNTs visible as bright lines on the SEM.

FIG. 9 illustrates that the structured film is continuous and is roughly a factor of 7.5 times thicker than the coating thickness of polysilicon. This increase in structured film thickness as compared with coating thickness is referred to herein as a growth amplification factor. In FIG. 9, a coating thickness of 0.6 μm and a structured film thickness of 4.5 μm provided a growth amplification factor of 4.5/0.6 or 7.5. This shows that it would take approximately 7.5 times longer to produce an equivalent film thickness when not using a structure similar to that provided in FIG. 9.

Referring now to FIG. 10A, multi-walled CNTs as high aspect ratio elements were grown in a tall 50 μm forest (structure) on a silicon substrate. The structure was filled to provide a coating thickness of 0.6 μm of polysilicon in about 40 minutes to provide a structured film that was approximately 44 μm thick. The 0.6 μm polysilicon coating incompletely filled the structure in a portion below the top surface, leaving some voids. The growth amplification factor for this structured film is approximately 75. Accordingly, it would require approximately 75 times longer to produce an equivalent film thickness when not using a structure similar to that provided in FIG. 10A. This growth amplification allows methods of the present invention to proceed in an amplified fashion, such that a structured film that is about 50 μm tall is now formed as compared with conventional deposition processes that would provide a film of only 600 nm on a planar structure (one without high aspect ratio elements).

FIG. 10B depicts multiwall CNTs as high aspect ratio elements grown in a tall 74 μm forest (structure) on a silicon substrate. The structure was filled to provide a coating thickness of 0.6 μm of polysilicon in about 4 hours (furnace temperature approximately 550 degrees Centigrade with a silane flow rate of 25 sccm). By providing a lower temperature and flow rate, the sticking coefficient of polysilicon was reduced which, as will be discussed further, improved coating of high aspect ratio elements along their entire surface leaving fewer voids (as compared with FIG. 10A). The structured film was approximately 74 μm thick. The growth amplification factor for the structured film is approximately 110. Accordingly, it would require approximately 110 times longer to produce an equivalent film thickness when not using a structure similar to that provided in FIG. 10B.

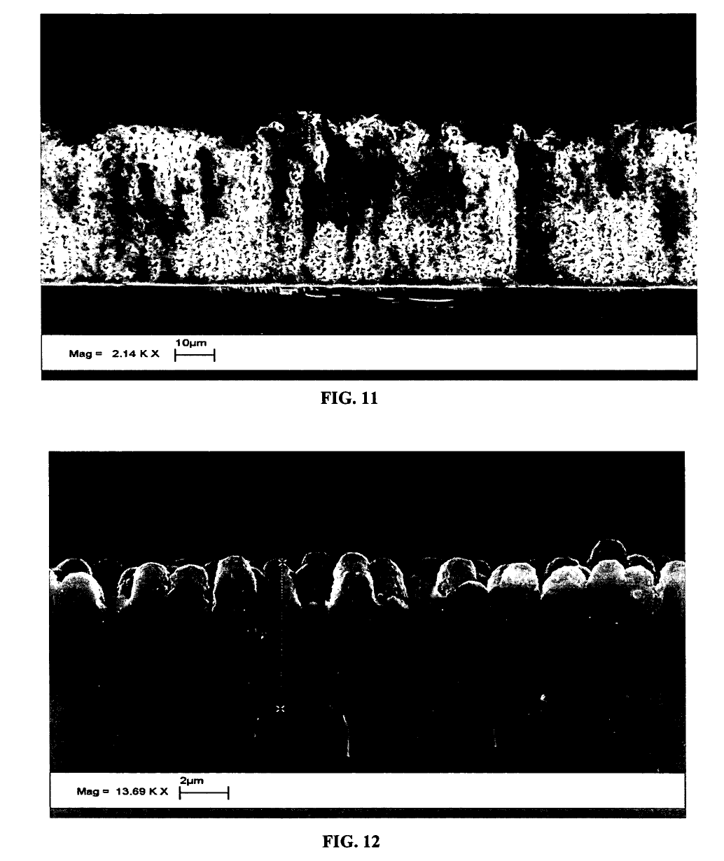

Referring now to FIG. 11, multi-walled CNTs as high aspect ratio elements were grown in a tall 50 μm forest (structure) on a silicon substrate. The structure was filled to provide a coating thickness of approximately 0.4 μm of Si₃N₄ by using LPCVD for 3 hours. The structured film was approximately 47 μm thick and incompletely filled in portions near the top and bottom of the structure. Increasing the coating time with Si₃N₄ will greatly reduce the fraction of voids, producing a more continuous film. The growth amplification factor for this structured film is approximately 120, but may overestimate the amplification factor due to incomplete filling.

Referring now to FIG. 12, a silicon wafer structure comprising a plurality of high aspect ratio holes etched into its surface (often referred to black silicon, as shown in FIG. 7) was filled by coating with polysilicon to a thickness of approximately 0.6 μm by LPCVD in a manner similar to that described above. Coating provided a structured film with a height of approximately 7 μm. Here, the growth amplification factor is approximately 11.

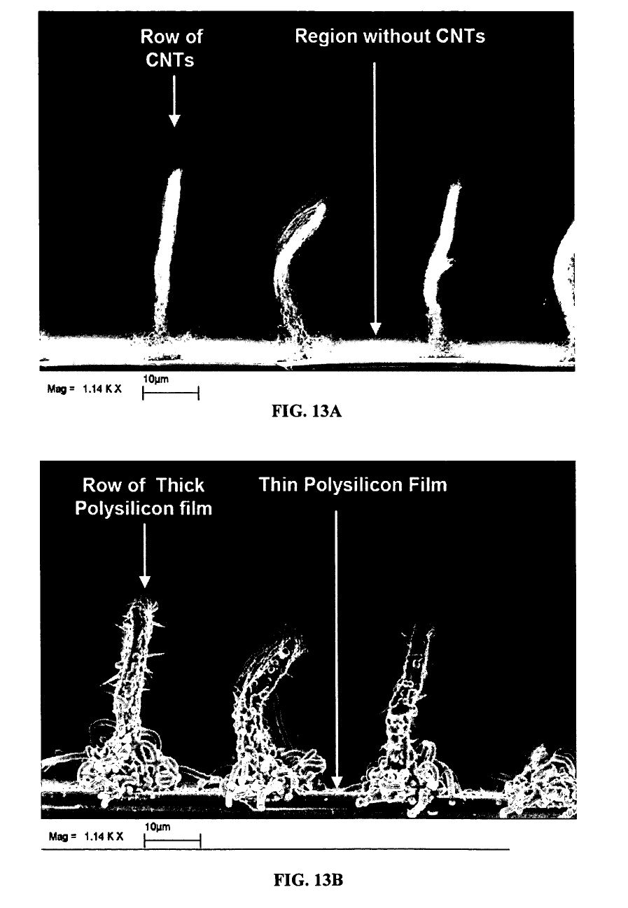

Referring now to FIG. 13A, the figure illustrates several structures that were fabricated on the same silicon substrate. Each structure included as-grown CNTs as high aspect ratio elements uniquely positioned and in distinctive shapes and/or sizes. The structures were filled by coating with polysilicon to a coating thickness of approximately 0.6 μm using LPCVD as described above. FIG. 13B shows the structures of FIG. 13A after filling and further illustrates that each structure retained their original shape and size. The thickness of polysilicon on the silicon substrate (see FIG. 13B) remained thin or nearly equivalent to the coating thickness of approximately 0.6 μm. The growth amplification factor for this structured film when using the typical height of each structure as approximately 35 μm is 60.

Further observations of filling, as performed on structures comprising 50 μm tall CNT forests showed that the solidifying material (e.g., both polysilicon and Si₃N₄) begins by growing uniformly around an individual CNT. As the solidifying material thickens, it bridges spaces between adjacent CNTs, thereby filling the forest and forming a structured film. Growth continues wherever there is an exposed surface that precursor molecules can contact. A greater number of precursor molecules tend to contact the ends of high aspect ratio elements (or uppermost portions of an element when residing or in contact with a support or substrate). Therefore, growth of the film is often faster in these portions. When the ends (or uppermost portions) become filled by the solidifying material, voids may result, such as those observed in FIGS. 10 and 11.

Methods described herein may be compared to film deposition inside a deep trench, as occurs in semiconductor processing, in which trench width is similar to the space between adjacent high aspect ratio elements and trench depth is similar to the height of the structure. With film deposition in a trench, deposition at any point on the trench sidewall is due to adsorption of an incoming precursor gas molecule and the transformation of the gas molecules to a solid state. This is akin to film deposition on a surface of a high aspect ratio element being due to adsorption of an incoming precursor gas molecule and the transformation of the gas molecules to a solid state. Accordingly, deposition thickness at any point is a product of the reactive sticking coefficient and the total number of impinging molecules.

Precursors to a solidifying material such as polysilicon have a sticking coefficient of approximately 10⁻³, while precursors to a solidifying material such as Si₃N₄ have a much smaller sticking coefficient of approximately 5×10⁻⁵. As such, for a solidifying material such as polysilicon, it is expected that a larger fraction of precursors stick to high aspect ratio elements at their uppermost portion (an example of an uppermost portion being shown in FIG. 3). Consequently, coating a plurality of high aspect ratio elements and, hence, filling, is improved when the sticking coefficient for precursor molecules is made smaller. For example, a sticking coefficients larger than 10⁻² will preferentially coat only the uppermost portion of a 50 ∥m tall structure of high aspect ratio element.

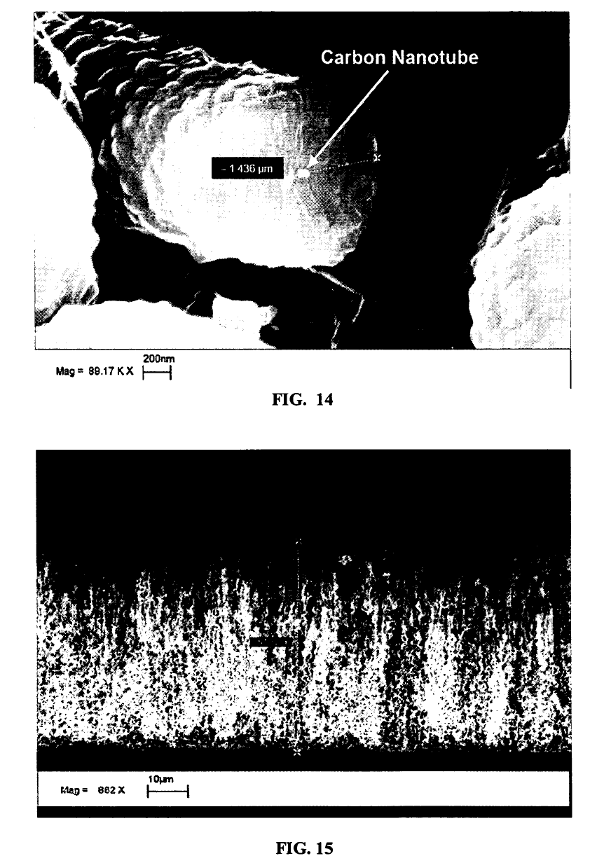

With the present invention, a solidifying material is deposited and coats around a high aspect ratio element and, thereby fills the structure. The coating is typically uniform or substantially uniform as shown in FIG. 14, in which an individual CNT is illustrated as having a uniform coating (as a film) of polysilicon.

The coating provided by the present invention increases the thickness of each individual high aspect ratio element which offers several advantages. One such advantage is that with the present invention there is an ability to control filling, such as partially filling or complete filling of a structure. Such control is not possible with many other techniques, such as liquid filling procedures and provides structured films of known porosity and/or known stoichiometry. An example of a partially filled structure is shown in FIG. 15, in which approximately 0.1 μm of Si₃N₄ coated CNTs of the forest structure. A partially filled structure as provided in FIG. 15 may be advantageous by providing enhanced connection to the substrate, increased scratch resistance and altered chemical behaviors as compared with the unfilled structure.

Another advantage is that there is an ability to layer disparate structured films in any desired sequence and at any thickness. Accordingly, the step of coating a plurality of high aspect ratio elements of a structure may be repeated as often as necessary to prepare a desired composition or device having one or more desired mechanical, physical, chemical, optical, biologic and/or electrical properties. The coating process may be repeated with the same solidifying material or with different solidifying materials.

Still another advantage is the present invention as described herein prevents the mere sticking of a solidifying material to the top of individual high aspect ratio elements (thereby, preventing capping) and allows the formation of a continuous structured film. Furthermore, high aspect ratio elements are not matted down with the present invention, which could greatly reduce the vertical height or length and/or alignment of such elements. Instead, the present invention provides structures that have retained their original size and/or shape. It negates the need of post-processing to ensure uniform dispersion of structures comprising high aspect ratio elements as compared with current (conventional) techniques required for making composite structures.

Post-processing techniques known to one of ordinary skill in the art may be provided to structures of the present invention when desired. Techniques may include chemical treatment (e.g., etching), physical treatment (e.g. chemical mechanical polishing), plasma treatment (e.g. surface modification), thermal treatment (e.g. annealing, melting, converting), optical treatment (e.g., irradiation) and combinations thereof. In addition, techniques may involve removing high aspect ratio elements and/or the substrate from the structure. Such techniques are well known to those of ordinary skill in the art.

In some embodiments, deposition of the one or more structures comprising a plurality of high aspect ratio elements and coating the plurality of high aspect ratio elements with one or more solidifying materials may be provided by the same CVD system. For example, as described herein, structures of up to and greater than 50 μm in height may be prepared and then filled to form a structured film in a continuous process.

Compositions and structured films formed by systems and methods of the present invention are typically at least twice as thick (in a given deposition time) as that achieved by conventional processes known in the art to one of ordinary skill. Structured films also exhibit reduced stress as compared to films formed without the initial structure (data not shown).

In accordance with various aspects of the present invention, structured films formed as described herein may be any desired thickness, hardness, density and have any desired electrical property by selection of the structure, its support, and/or solidifying material. In addition, methods as described herein may be varied to provide a desired structured film density, hardness and/or thickness. In another form, the present method provides for fabricating compositions in the absence of a support or substrate (e.g., a stand-alone platform).

The present invention helps overcome the current inability to deposit typical electronic and MEMS materials like polysilicon, silicon nitride, metals and polymers of thicknesses greater than a few micrometers. Current deposition techniques are slow (typically 1 μm per hour). Thus depositing films that are tens of micrometers thick becomes infeasible. In addition, the internal stress in such thick films can become high leading to various film degradation effects. The present invention overcomes such limitation by incorporating and coating around high aspect ratio elements to provide a structured film that alleviates the stress in the film. The reduced stress is, in part, due to the inherent strength of high aspect ratio elements as described herein. In addition, as a result of having structures with high aspect elements, structures now have an increased surface area (and sites) available for adsorption and subsequent coating as compared with a comparative structure (or support or substrate) absent high aspect ratio elements.

While particular embodiments of the invention have been described herein, additional alternatives not specifically disclosed but known in the art are intended to fall within the scope of the invention. Thus, it is understood that other embodiments and applications of the present invention will be apparent to those skilled in the art without departing from the scope and spirit of the appended claims and drawings.

1. A method of filling a structure comprising the steps of:
providing one or more structures, each structure having a plurality of high aspect ratio elements, wherein the aspect ratio is at least 5; and
coating the plurality of high aspect ratio elements with at least one solidifying material produced by a form of chemical vapor deposition thereby forming a structured-film.

2. The method of claim 1, wherein coating produces voids in the structured film.

3. The method of claim 1, wherein the at least one solidifying material provides one or more properties to the structure, the one or more properties including electrical, mechanical, optical, biologic, and chemical.

4. The method of claim 1, wherein the high aspect ratio elements are shaped as holes, trenches, black silicon, nanotubes, nanofibers, nanopillars, nanocones, nanowires, columns, posts, glancing-angle deposits and combinations thereof.

5. The method of claim 1, wherein the one or more structures are arranged in a form including a forest, yarn, paper, fiber, filter, membrane or string.

6. The method of claim 1, wherein the one or more structures are on a substrate.

7. The method of claim 1, wherein filling provides a structured film that is thicker than that prepared by conventional processes.

8. The method of claim 1, wherein the form of chemical vapor deposition includes low pressure chemical vapor deposition, atmospheric pressure chemical vapor deposition, plasma enhanced chemical vapor deposition, metal organic chemical vapor deposition and atomic layer deposition.

9. The method of claim 1, wherein the step of coating is repeated one or more times to produce a layered structured film.

10. The method of claim 1 wherein the step of coating is followed by a post-filling process, wherein the post-filling process includes heating, irradiation, chemical treatment, plasma treatment, optical treatment, chemical mechanical polishing, etching, removing the plurality of high aspect ratio elements, removing the substrate and combinations thereof.

11. The method of claim 1, wherein the method provides a device, wherein the device includes an electrical device, a membrane, filter, lattice, template and sensor.

12. The method of claim 1, wherein providing the one or more structures are produced by a form of chemical vapor deposition.

13. A device prepared by the method of claim 1.

14. A composition prepared by the method of claim 1.

15. A composition comprising:
one or more structures, each structure having a plurality of high aspect ratio elements, wherein the aspect ratio is at least 5, and wherein the plurality of high aspect ratio elements are coated with at least one solidifying material produced by a form of chemical vapor deposition thereby forming a structured-film.

16. The composition of claim 15, wherein the one or more structures are selectively positioned.

17. The composition of claim 15, wherein the one or more structures have one or more properties, the one or more properties including electrical, mechanical, optical, biologic, and chemical.

18. The composition of claim 15, wherein the composition is included in a device, the device including an electronic device, optical device, thermal device, mechanical device, electro-chemical devices, and micro-electro-mechanical systems device.

19. The composition of claim 15, wherein structured film has voids.

20. The composition of claim 15, wherein the at least one solidifying material provides one or more properties to the structure, the one or more properties including electrical, mechanical, optical, biologic, and chemical.

21. The composition of claim 15, wherein the high aspect ratio elements are shaped as holes, trenches, black silicon, nanotubes, nanofibers, nanopillars, nanocones, nanowires, columns, posts, glancing-angle deposits and combinations thereof.

22. The composition of claim 15, wherein the one or more structures are arranged in a form including a forest, yarn, paper, fiber, filter, membrane or string.

23. The composition of claim 15, wherein composition includes a substrate.

24. The composition of claim 15, wherein the form of chemical vapor deposition includes low pressure chemical vapor deposition, atmospheric pressure chemical vapor deposition, plasma enhanced chemical vapor deposition, metal organic chemical vapor deposition and atomic layer deposition.

25. The composition of claim 15, wherein the composition is further processed by a treatment including heating, irradiation, chemical treatment, plasma treatment, optical treatment, chemical mechanical polishing, etching, removing the plurality of high aspect ratio elements, removing the substrate and combinations thereof.

26. The composition of claim 15, wherein the one or more structures are produced by a form of chemical vapor deposition.

27. A device comprising the composition of claim 15.

28. The method of claim 1, wherein a ratio for the overall dimension of the structure to a spacing between adjacent high aspect ratio elements is typically 5 or greater.

29. The composition of claim 15, wherein a ratio for the overall dimension of the structure to a spacing between adjacent high aspect ratio elements is typically 5 or greater.
